(19) United States
(12) Patent Application Publication
(10) Pub. No.: US 2014/0033521 A1
(43) Pub. Date: Feb. 6, 2014

(54) EXTRACTOR AND EXTRACTING DEVICE

(71) Applicant: FUJITSU LIMITED, Kawasaki-shi (JP)

(72) Inventor: Yoshiharu NISHIJIMA, Tubata (JP)

(73) Assignee: FUJITSU LIMITED, Kawasaki-shi (JP)

(21) Appl. No.: 13/903,352

(22) Filed: May 28, 2013

(30) Foreign Application Priority Data
Jul. 31, 2012 (JP) 2012-170021

(51) Int. Cl. H05K 13/04

(52) U.S. Cl. CPC H05K 13/0491
USPC 29/764

(57) ABSTRACT

An extractor includes an attachment portion that has at least one groove receiving a side portion of a board connected to a connector and that is attached to the side portion of the board, a tongue portion that extends from a side portion of the at least one groove in the attachment portion along the extension direction of the at least one groove and that is engaged with the inner surface of a latch, the board being pushed up by inclining toward the side of the board, and an operating portion that extends from the attachment portion in the opposite direction from the tongue portion.

### CROSS-REFERENCE TO RELATED APPLICATION

This application is based upon and claims the benefit of priority of the prior Japanese Patent Application No. 2012-170021, filed on Jul. 31, 2012, the entire contents of which are incorporated herein by reference.

### FIELD

The embodiments discussed herein are related to an extractor and an extracting device.

### BACKGROUND

There have been connectors for connecting memory cards, such as dual inline memory modules (DIMMs). In such connectors, with the recent increase in the capacity of memories in electronic computers and the like, the increase in the number of pins and the reduction in height are progressing.

However, the increase in the number of pins of a connector connected with a board such as a memory card leads to the increase in the force that is used to insert and extract the board, and the reduction in the height of a connector reduces the length of arms of latches provided in the connector when the latches are inclined, and increases the operating force at the time of extraction of the board. In addition, in circuit boards on which such connectors are mounted, the density of mounting is increasing. When connectors are placed in a narrow space or behind other components owing to the increase in the density of mounting on circuit boards, it is difficult to operate latches with fingers. Related arts are disclosed in Japanese Laid-open Patent Publication Nos. 2007-87610, 2-256471, 6-245348, and 2008-71599.

### SUMMARY

According to an aspect of the invention, an extractor includes an attachment portion that has at least one groove receiving a side portion of a board connected to a connector and that is attached to the side portion of the board, a tongue portion that extends from a side portion of the at least one groove in the attachment portion along the extension direction of the at least one groove and that is engaged with the inner surface of a latch, the board being pushed up by inclining toward the side of the board, and an operating portion that extends from the attachment portion in the opposite direction from the tongue portion.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a perspective view of extractors, a connector, and a memory card according to a first embodiment;

FIG. 2 is a front view illustrating a state where the extractors according to the first embodiment are attached to the memory card and latches;

FIG. 3 is a right side view of FIG. 2;

FIG. 4 is a sectional view taken along line IV-IV of FIG. 2;

FIG. 5 is a diagram illustrating how the memory card is extracted from the connector using the extractor according to the first embodiment;

FIG. 6 is a perspective view of an extractor according to a second embodiment;

FIG. 7 is a perspective view of the extractor of FIG. 6 seen from another direction;

FIG. 8 is a three-view drawing of an extracting device according to a third embodiment;

FIG. 9 is an exploded perspective view of the extracting device of FIG. 8;

FIG. 10 is a three-view drawing of an extracting device according to a fourth embodiment; and

FIG. 11 is an exploded perspective view of the extracting device of FIG. 10.

### DESCRIPTION OF EMBODIMENTS

### First Embodiment

A first embodiment will be described.

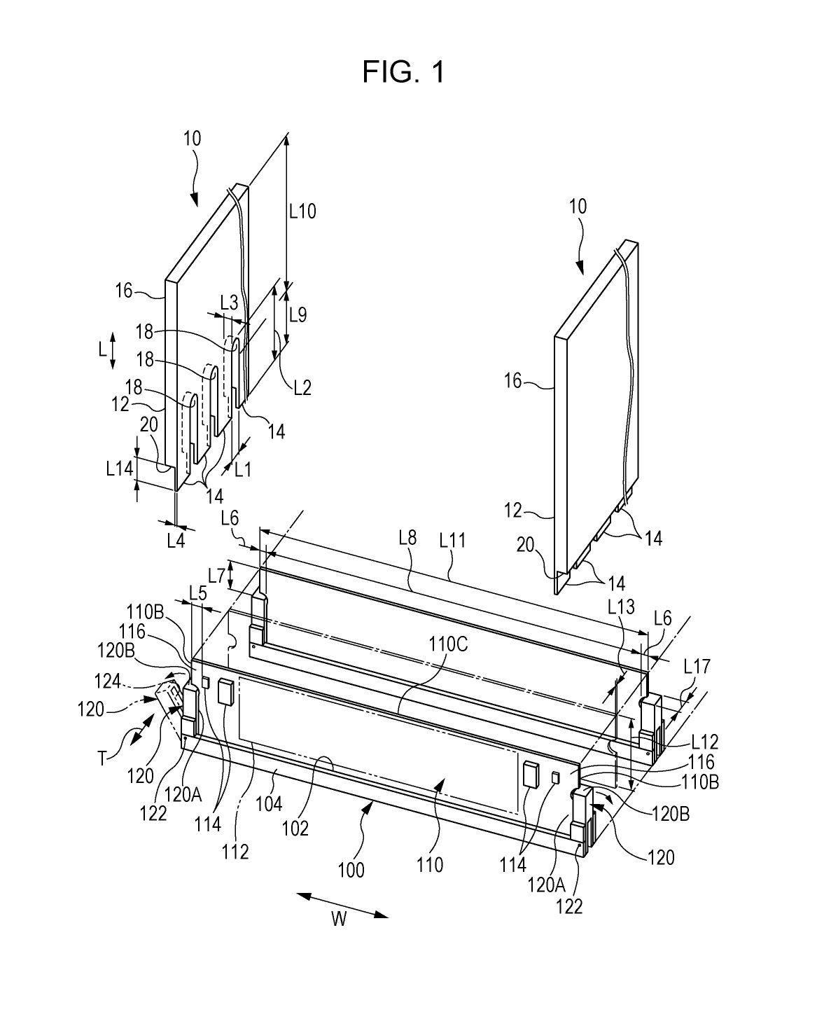

Before describing the specific configuration of extractors 10 according to the first embodiment illustrated in FIG. 1, connectors 100 and memory cards 110 for which the extractors 10 are used will be described.

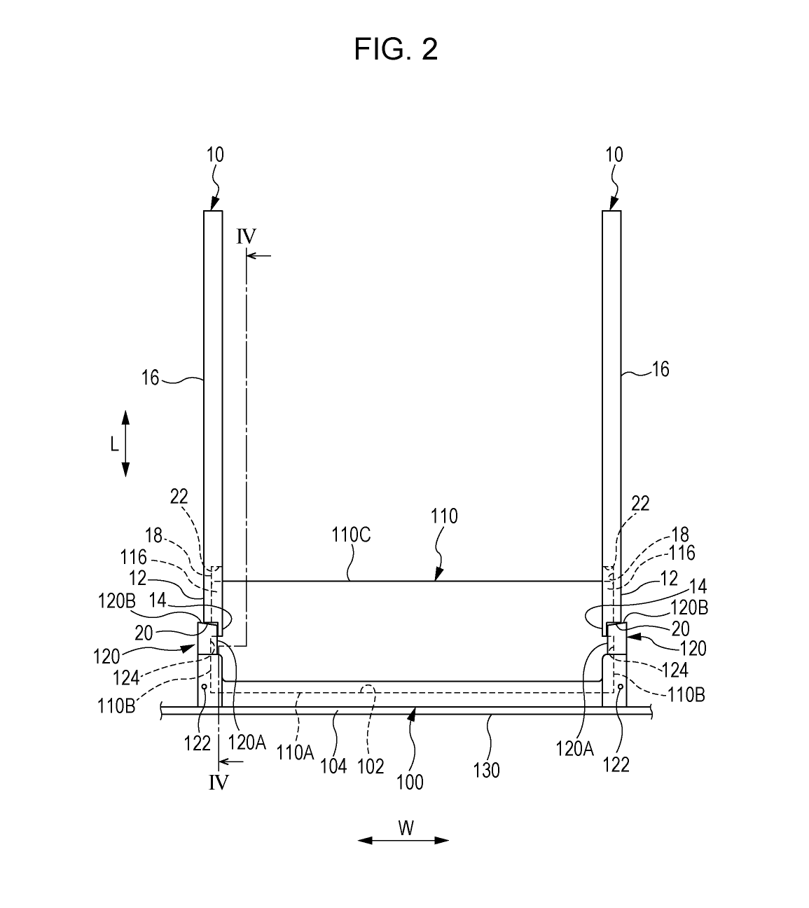

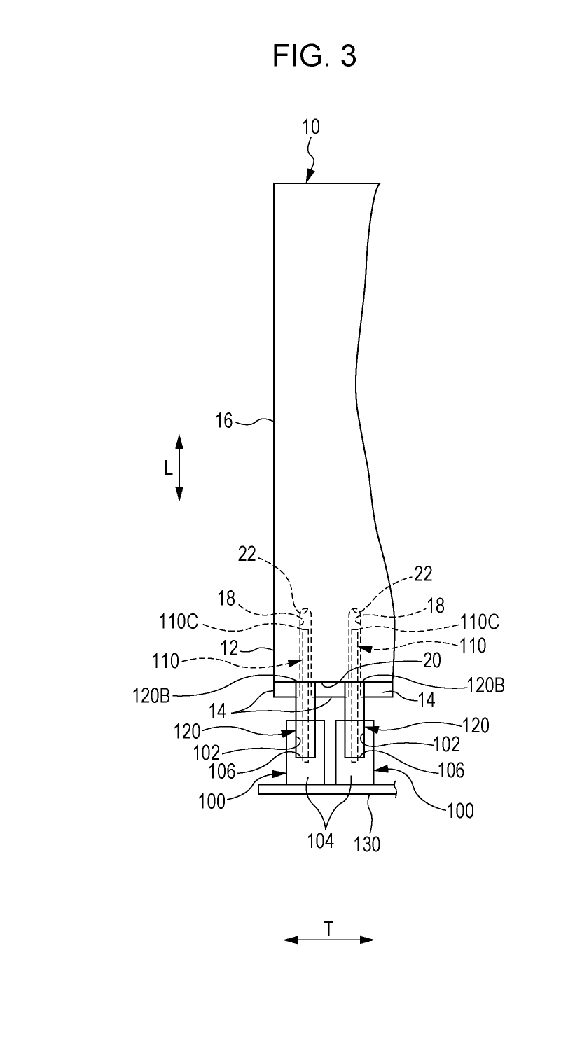

The connectors 100 correspond, for example, to the dual inline memory module (DIMM) standard. The connectors 100 are mounted on a circuit board 130 (see FIG. 2 and FIG. 3). The connectors 100 are formed in an elongated shape and have groove-like connecting portions 102. The connecting portions 102 extend in the longitudinal direction of the connectors 100 (that is, the direction of arrow W, which is the width direction). The lower ends of the memory cards 110 are inserted into and connected to the connecting portions 102.

The memory cards 110 are an example of a board, and are, for example, DIMMs. A memory 112, electronic circuit components 114, and the like are mounted on each memory card 110. The memory cards 110 and the connectors 100 are arranged parallel to each other. A latch 120 is provided at each end of each connector 100.

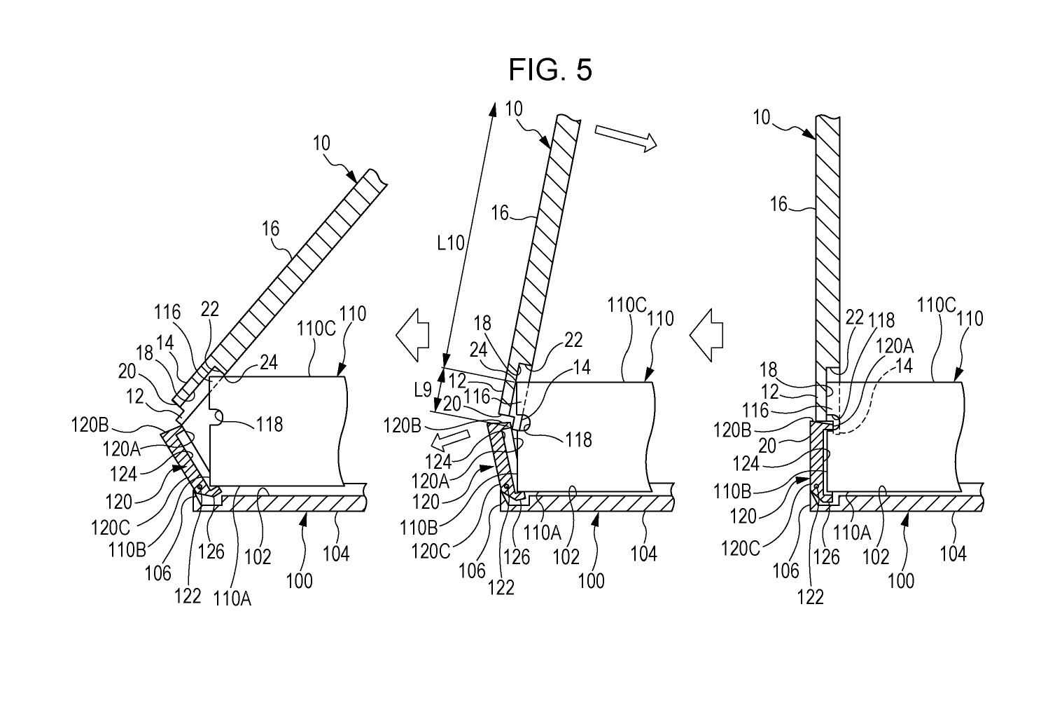

The latch 120 is supported rotationally relative to the connector 100 by a rotating shaft 122 extending in the thickness direction of the memory card 110 connected to the connecting portion 102 of the connector 100 (the direction of arrow T). The latch 120 is capable of being brought into a state where it is raised and disposed along the side portion 116 of the memory card 110, and a state where it is inclined toward the side of the memory card 110 (see FIG. 5).

As illustrated in FIG. 5, an engaging recess 124 that is open toward the memory card 110 is formed in the latch 120. When the memory card 110 is connected to the connector 100 and the latch 120 is disposed along the side portion 116 of the memory card 110, the engaging recess 124 is engaged with the side portion 116 (a part below the recess 118) of the memory card 110. By engaging the side portion 116 of the memory card 110 with the engaging recess 124, the extraction of the memory card 110 from the connector 100 is restricted.

At the lower end of the latch 120, a claw portion 126 protruding toward the middle in the width direction of the connector 100 is formed. When the memory card 110 is connected to the connector 100 and the latch 120 is disposed along the side portion 116 of the memory card 110, the claw portion 126 is engaged with the lower surface 110A of the memory card 110. When the latch 120 is inclined toward the side of the memory card 110, the claw portion 126 pushes up the memory card 110, and the memory card 110 is disconnected from the connector 100.

An upwardly protruding stopper 106 is formed in the side portion of a bottom wall portion 104 formed in the connector 100. When, as described above, the latch 120 is inclined and the memory card 110 is disconnected from the connector 100, the stopper 106 comes into contact with a part of the latch 120 (more specifically, a part of the outer surface 120C closest to the rotating shaft 122). The stopper 106 restricts the inclination of the latch 120 by being brought into contact with a part of the latch 120.

In the above description, for the sake of convenience, the direction in which the memory card 110 is inserted into and extracted from the connector 100 is referred to as a top-bottom direction. However, the top-bottom direction does not correspond to the vertical direction (the direction of gravitational force).

Next, the specific configuration of the extractors 10 according to the first embodiment will be described.

The extractors 10 are for the purpose of inclining the latches 120 and extracting the memory card 110 from the connector 100. As illustrated in FIG. 1, each extractor 10 functionally includes an attachment portion 12, a plurality of tongue portions 14, and an operating portion 16.

The attachment portion 12 corresponds to the distal end part of the extractor 10 and has a plurality of grooves 18 arranged parallel to each other. The plurality of grooves 18 are open on one side in the thickness direction of the extractor 10 (so as to face the memory card 110) and extend along the length direction of the extractor 10 (the direction of arrow L). The end of each groove 18 closest to the distal end of the extractor 10 is open toward the distal end of the extractor 10. The end of each groove 18 closest to the rear end of the extractor 10 is terminated.

As described later, the side portion 116 (the part closest to the side surface 110B) of the memory card 110 is inserted into each groove 18. The number of the grooves 18 is selected according to the number of memory cards 110 to be extracted. The width L1 of each groove 18 is set greater than the thickness L13 of the memory card 110 so that the side portion 116 of the memory card 110 may slide freely in the groove 18. If the depth of the grooves 18 is denoted as L3, and the distance between the component mounted on the memory card 110 and placed closest to the side surface 110B of the memory card 110 and the side surface 110B of the memory card 110 is denoted as L5, L3<L5.

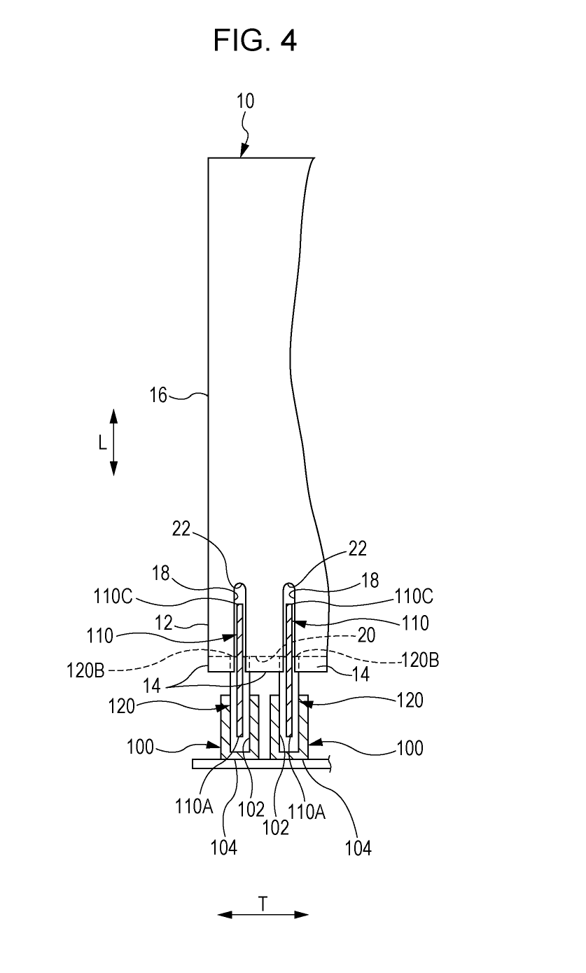

A stepped surface 20 facing toward the distal end of the extractor 10 is formed at the end of the attachment portion 12 closest to the distal end of the extractor 10 (closest to the tongue portions 14 described later). When the latch 120 is disposed along the side portion 116 of the memory card 110, and the side portion 116 of the memory card 110 is inserted into the groove 18 through the distal end of the extractor 10, the stepped surface 20 is brought into contact with the upper end surface 120B of the latch 120 (see FIG. 2 to FIG. 5).

By inserting the side portion 116 of the memory card 110 into the groove 18 and bringing the stepped surface 20 into contact with the upper end surface 120B of the latch 120, the attachment portion 12 is attached to the side portion 116 of the memory card 110 (see FIG. 2). The position of an end wall portion 22 on the opposite side of the groove 18 from the tongue portions 14 is set such that when the stepped surface 20 is in contact with the upper end surface 120B of the latch 120, a gap is formed between the end wall portion 22 and the upper end surface 110C of the memory card 110. Specifically, if, as illustrated in FIG. 1, the length of the grooves 18 is denoted as L2, the distance between the upper end surface 120B of the latch 120 and the upper end surface 110C of the memory card 110 is denoted as L7, and the length of the tongue portions 14 is denoted as L14, L2>(L7+L14).

The plurality of tongue portions 14 extend from the side portions of each of the plurality of grooves 18 of the attachment portion 12 (portions on both sides of each groove 18), along the extension direction of the grooves 18. The plurality of tongue portions 14 form the distal end portion of the extractor 10. When the memory card 110 is connected to the connector 100 and the attachment portion 12 is attached to the side portion 116 of the memory card 110, the plurality of tongue portions 14 are engaged with the upper end of the inner surface 120A of the latch 120 (see FIG. 2 and FIG. 5).

The inner surface 120A of the latch 120 is a surface that faces toward the middle in the width direction of the memory card 110 when the latch 120 is raised and disposed along the side portion 116 of the memory card 110. If the thickness of the tongue portions 14 is denoted as L4, the distance between the inner surfaces 120A of the latches 120 on both sides is denoted as L8, and the width of the memory card 110 is denoted as L11, a relationship of L4<(L5−L6) is satisfied. However, L6=(L11−L8)/2.

The operating portion 16 is a portion that is operated by an operator (a portion to which the operating force is applied), and extends from the attachment portion 12 in the opposite direction from the tongue portions 14. The operating portion 16 forms a part between the attachment portion 12 and the rear end of the extractor 10 and has such a size that an operator is able to hold it with their fingers. The operating portion 16 has a sufficient length so that when the memory card 110 is connected to the connector 100 and the attachment portion 12 is attached to the side portion 116 of the memory card 110, the operating portion 16 protrudes above the memory card 110.

As illustrated in FIG. 5, the operating portion 16 is inclined toward the middle in the width direction of the memory card 110, with the attachment portion 12 attached to the side portion 116 of the memory card 110. The rotation fulcrum 24 at this time is the contact point between the bottom of the groove 18 and the upper corner of the memory card 110. The depth of the bottom of the groove 18 is set such that the extractor 10 rotates about such a rotation fulcrum 24. The upper corner of the memory card 110 serving as a rotation fulcrum 24 may be chamfered or rounded off.

When the operating portion 16 is inclined and the tongue portions 14 move toward the side of the memory card 110, the upper end of the inner surface 120A of the latch 120 is pushed by the distal ends of the tongue portions 14 toward the side of the memory card 110. The length of the tongue portions 14 is set such that the tongue portions 14 are in contact with the inner surface 120A of the latch 120 until the inclined latch 120 comes into contact with the stopper 106. The length of the tongue portion 14 is set such that when the inclined latch 120 comes into contact with the stopper 106, the tongue portions 14 are disengaged from the inner surface 120A of the latch 120.

The position of the end wall portion 22 is set such that when the memory card 110 is pushed up and disconnected from the connector 100, the corner of the end wall portion 22 comes into contact with the upper end surface 110C of the memory card 110.

The lengths of the tongue portions 14 and the operating portion 16 are set such that if the distance from the rotation fulcrum 24 (see the middle portion of FIG. 5) to the distal ends of the tongue portions 14 is denoted as L9, and the distance from the rotation fulcrum 24 to the rear end of the operating portion 16 is denoted as L10, L10 is greater than L9. L9 is an example of a first distance, and L10 is an example of a second distance.

Each extractor 10 integrally has an attachment portion 12, a plurality of tongue portions 14, and an operating portion 16. Such extractors 10 are preferably made of resin and formed by injection molding or formed by cutting an injection-molded plate.

Next, a description will be given of how to extract the memory card 110 from the connector 100 using the above-described extractors 10.

As illustrated in FIG. 1, the above-described extractors 10 are used for the latches 120 provided on both sides of the connectors 100. This pair of extractors 10 is operated symmetrically. So, hereinafter, only one of the extractors 10 will be described, and the description of the other extractor 10 will be omitted.

First, as illustrated in the right portion of FIG. 5, the attachment portion 12 of the extractor 10 is attached to the side portion 116 of the memory card 110 connected to the connector 100. That is, the side portion 116 of the memory card 110 is inserted into the groove 18 through the distal end of the extractor 10, and the side portion 116 of the memory card 110 is slid in the groove 18 until the stepped surface 20 comes into contact with the upper end surface 120B of the latch 120. When the attachment portion 12 is attached to the side portion 116 of the memory card 110, the tongue portions 14 are engaged with the upper end of the inner surface 120A of the raised latch 120. At this time, more specifically, a pair of tongue portions 14 located on both sides of each groove 18 are engaged with the inner surface 120A of the latch 120 on both sides of the memory card 110.

As illustrated in the middle portion of FIG. 5, the operating portion 16 is rotated about a rotation fulcrum 24 that is the contact point between the bottom of the groove 18 and the upper corner of the memory card 110 (the intersection of the side surface 1106 with the upper end surface 110C) toward the middle in the width direction of the memory card 110. When the operating portion 16 is inclined, the upper end of the inner surface 120A of the latch 120 is pushed toward the side of the memory card 110, and the latch 120 is inclined toward the side of the memory card 110.

When the latch 120 is inclined toward the side of the memory card 110, the engaging recess 124 formed in the latch 120 is disengaged from the side portion 116 of the memory card 110. As the latch 120 is inclined toward the side of the memory card 110, the memory card 110 is pushed up by the claw portion 126 of the latch 120. As the memory card 110 is pushed up, the above-described rotation fulcrum 24 is moved toward the end wall portion 22 of the groove 18, that is, upwardly.

As illustrated in the left portion of FIG. 5, when the inclined latch 120 comes into contact with the stopper 106, the memory card 110 is disconnected from the connector 100. When the memory card 110 is pushed up and disconnected from the connector 100, the tongue portions 14 are disengaged from the inner surface 120A of the latch 120. That is, when, after the memory card 110 is disconnected from the connector 100, the latch 120 is further inclined, the latch 120 is brought into contact with the stopper 106, and the tongue portions 14 are disengaged from the inner surface 120A of the latch 120.

When the memory card 110 is disconnected from the connector 100, the corner of the end wall portion 22 is in contact with the upper end surface 110C of the memory card 110. The rotation fulcrum moves to the contact point between the corner of the end wall portion 22 and the upper end surface 110C of the memory card 110, and the increase in the distance from the rotation fulcrum to the distal ends of the tongue portions 14 is restricted. Thus, a state where the tongue portions 14 are disengaged from the inner surface 120A of the latch 120 is maintained.

Next, the working and advantageous effects of the first embodiment will be described.

As described above in detail, according to the first embodiment, the memory card 110 is extracted from the connector 100 by inclining the latch 120 toward the side of the memory card 110 using the extractor 10. The memory card 110 may be extracted with the extractor 10 using the principle of leverage. Therefore, even if the connector 100 has many pins and a low profile, the operating force of the latch 120 (the force that is used to pull out the memory card 110) may be reduced. The operation at the time of the extraction of the memory card 110 is thereby facilitated.

The attachment portion 12 has a plurality of grooves 18, and tongue portions 14 extend from the side portions of each of the plurality of grooves 18. Therefore, a plurality of memory cards 110 may be extracted at once with a single extractor 10.

At the end of the attachment portion 12 closest to the tongue portions 14, a stepped surface 20 that is brought into contact with the upper end surface 120B of the latch 120 is formed. When the latch 120 is disposed along the side portion 116 of the memory card 110, and the side portion 116 of the memory card 110 is inserted into the groove 18 through the distal end of the extractor 10, the stepped surface 20 is brought into contact with the upper end surface 120B of the latch 120. Therefore, the attachment portion 12 is attached to the side portion 116 of the memory card 110 by sliding the side portion 116 of the memory card 110 in the groove 18 until the stepped surface 20 is brought into contact with the upper end surface 120B of the latch 120. Thus, the attachment of the attachment portion 12 to the side portion 116 of the memory card 110, that is, the setting up of the extractor 10 is easy.

When the stepped surface 20 is in contact with the upper end surface 120B of the latch 120, a gap is formed between the end wall portion 22 on the opposite side of the groove 18 from the tongue portions 14 and the upper end surface 110C of the memory card 110. Therefore, when the memory card 110 is pushed up, and the rotation fulcrum 24 of the extractor 10 is thereby moved toward the end wall portion 22 of the groove 18 (upwardly), the interference between the upper end surface 110C of the memory card 110 and the end wall portion 22 may be suppressed. Thus, the memory card 110 may be smoothly extracted.

When the memory card 110 is pushed up and disconnected from the connector 100, the rotation fulcrum 24 moves to the contact point between the corner of the end wall portion 22 and the upper end surface 110C of the memory card 110. In this state, the tongue portions 14 are disengaged from the inner surface 120A of the latch 120. Therefore, the latch 120 may be kept from being needlessly inclined and damaged by the interference with the stopper 106.

The distance L10 from the rotation fulcrum 24 to the rear end of the operating portion 16 is greater than the distance L9 from the rotation fulcrum 24 to the distal ends of the tongue portions 14. Therefore, by using the principle of leverage, the operating force applied to the operating portion 16 in order to pull out the memory card 110 may be reduced.

Next, a modification of the first embodiment will be described.

Although, in the first embodiment, latches 120 are provided on both sides of the connector 100, a latch 120 may be provided on one side.

Although, in the first embodiment, the attachment portion 12 has a plurality of grooves 18, the attachment portion 12 may have a single groove 18. That is, although, in the first embodiment, the extractors 10 are configured to extract a plurality of memory cards 110 at once, the extractors 10 may be configured to extract a single memory card 110.

Although, in the first embodiment, the memory cards 110 are DIMMs, and the connectors 100 correspond to the DIMM standard, the memory cards 110 and the connectors 100 may be products other than DIMM-standard products.

Although, in the first embodiment, memory cards 110 are connected to the connectors 100, other boards may be connected.

### Second Embodiment

Next, a second embodiment will be described.

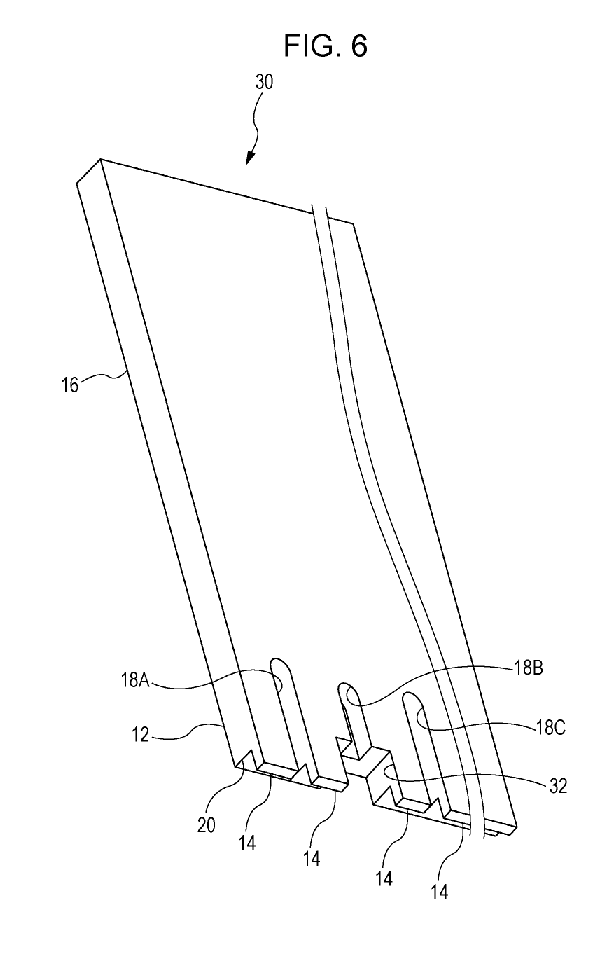

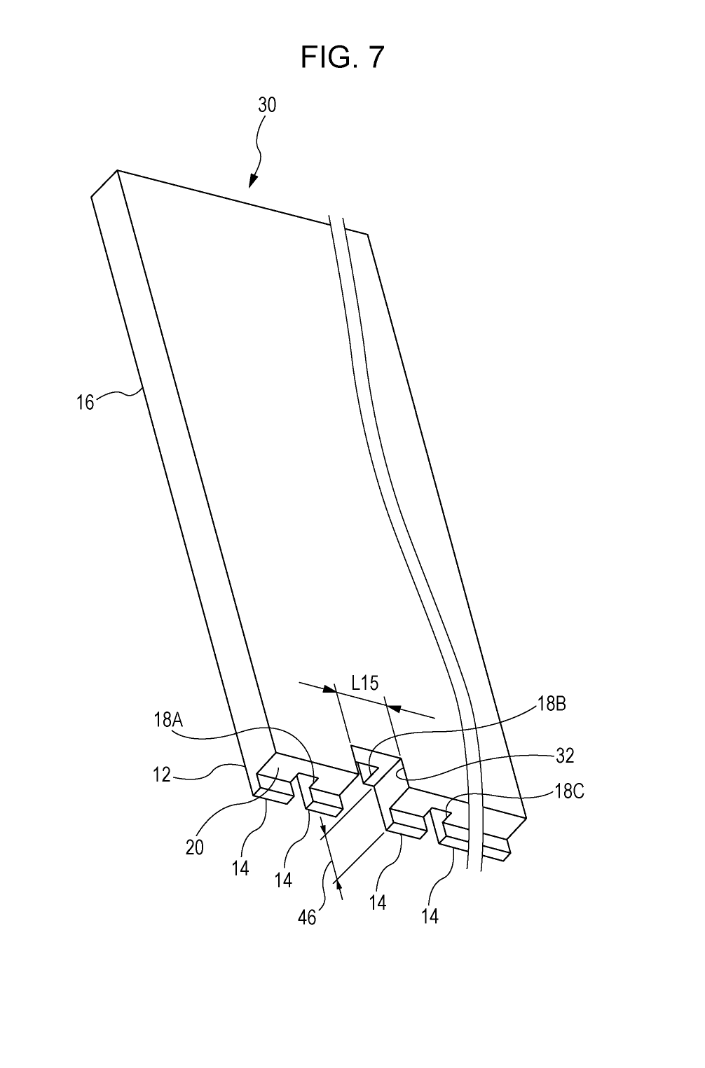

An extractor 30 illustrated in FIG. 6 and FIG. 7 differs from the extractors 10 according to the first embodiment in the following respects.

Tongue portions 14 extend from the side portions of each of the grooves 18A and 18C, whereas tongue portions 14 are omitted from the side portions of the groove 18B. The grooves 18A to 18C are formed in the same manner as the grooves 18 in the first embodiment. The attachment portion 12 has a cutout 32 that is formed at a position corresponding to the groove 18B and that extends in the opposite direction from the direction in which the tongue portions 14 extend. The cutout 32 is formed at a position corresponding to one of a plurality of memory cards 110 arranged parallel to each other (see FIG. 1) that is not extracted. The width L15 of the cutout 32 is set such that the adjacent tongue portions 14 are not engaged with the latch 120 (see FIG. 1).

That is, the width L15 of the cutout 32 is greater than the width L17 of the latch 120, and is set such that L15>L17+(L1−L13) in view of the backlash of the memory card 110 in the groove 18. L13 is the thickness of the memory card 110. The depth of the cutout 32 is set such that the edge of the cutout 32 is not engaged with the latch 120 holding the memory card 110 that is not extracted.

Since the cutout 32 is formed, the extractor 30 of the second embodiment may extract the memory cards that are desired to be extracted at once, while leaving the memory card that is not extracted. This extractor is useful, for example, in a case where after memory cards are connected to a plurality of connectors provided in a device, and the function of the device is checked, the pattern in which the memory cards are mounted is changed. That is, by preparing an extractor 30 in which cutouts 32 are formed according to the pattern in which the memory cards are mounted, a specified mounting pattern may be flexibly performed in a short time.

### Third Embodiment

Next, a third embodiment will be described.

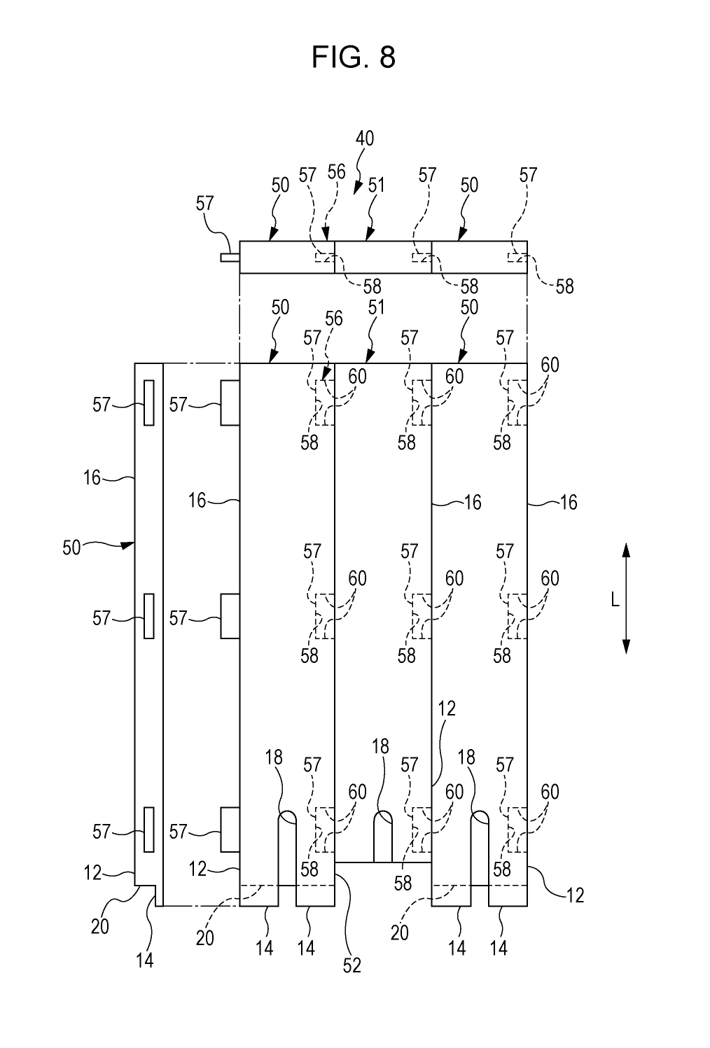

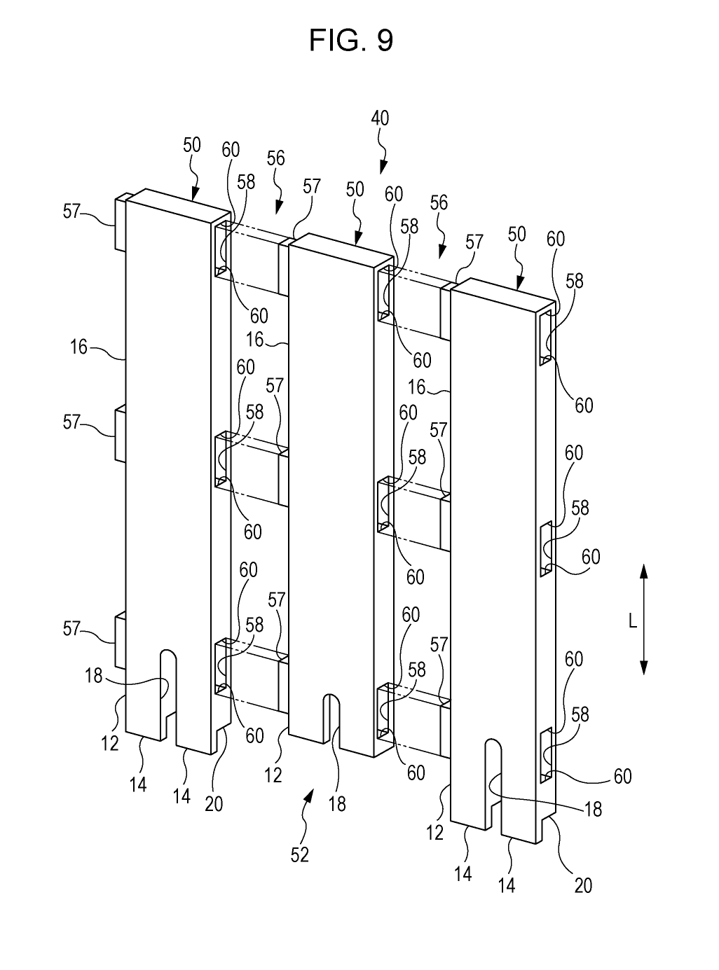

An extracting device 40 according to the third embodiment illustrated in FIG. 8 and FIG. 9 includes a plurality of extractors 50 and a connecting component 51. Unlike the extractors 10 according to the first embodiment, each extractor 50 has a single groove 18 and a pair of tongue portions 14 extending from both side portions of the single groove 18.

The connecting component 51 is placed between adjacent extractors 50 and connects the adjacent extractors 50 to each other. From the connecting component 51, the tongue portions 14 are omitted so that the distal end portion of the connecting component 51 is short compared to those of the extractors 50. When placed between adjacent extractors 50, the connecting component 51 forms a cutout 52 extending in the opposite direction from the direction in which the tongue portions 14 extend, between the tongue portions 14 of the adjacent extractors 50.

The cutout 52 is formed at a position corresponding to one of a plurality of memory cards 110 arranged parallel to each other (see FIG. 1) that is not extracted. The size of the cutout 52 is set such that the edge of the cutout 52 is not engaged with the latch 120 (see FIG. 1) holding the memory card 110 that is not extracted.

The plurality of extractors 50 and the connecting component 51 are connected by connecting portions 56. The connecting portions 56 each have a plurality of connecting protrusions 57 and a plurality of connecting recesses 58. The connecting protrusions 57 are formed on one side of each of the extractors 50 and the connecting component 51, and the connecting recesses 58 are formed in the other side of each of the extractors 50 and the connecting component 51. The connecting protrusions 57 are capable of being fitted in any one of the connecting recesses 58. In the extractors 50 and the connecting component 51, the connecting protrusions 57 and the connecting recesses 58 are formed at the same positions and in the same shape. By the connecting portions 56, the plurality of extractors 50 and connecting component 51 are connected such that they may be rearranged.

In each extractor 50, the wall portions on both sides of each connecting recess 58 in the length direction of the extractor 50 (the direction of arrow L) are formed as engaging wall portions 60 that are engaged with the connecting protrusion 57. Similarly, in the connecting component 51, the wall portions on both sides of each connecting recess 58 in the length direction of the connecting component 51 are formed as engaging wall portions 60 that are engaged with the connecting protrusion 57.

In the extracting device 40 according to the third embodiment, the connecting component 51 forms a cutout 52 extending in the opposite direction from the direction in which the tongue portions 14 extend, between the tongue portions 14 of the adjacent extractors 50. Therefore, as with the second embodiment, the extracting device 40 may extract the memory cards that are desired to be extracted at once, while leaving the memory card that is not extracted.

In the extractor 40, the plurality of extractors 50 and the connecting component 51 may be rearranged. Therefore, the position of the connecting component 51, that is, the position of the cutout 52 may be set arbitrarily. Thus, the memory card that is not extracted may be freely chosen. The number of extractors 50 may also be freely chosen. Thus, the number of memory cards that are extracted at once may be adjusted.

The connecting component 51 is the same as the extractor 50 from which the tongue portions 14 are omitted (the connecting component 51 is the same shape as the extractors 50 except that the tongue portions 14 are omitted so that the distal end portion of the connecting component 51 is short compared to those of the extractors 50). Therefore, the connecting component 51 may be easily formed.

When the connecting protrusions 57 are fitted in the connecting recesses 58, each connecting protrusion 57 is engaged with the engaging wall portions 60 in the length direction of the extractors 50 and the connecting component 51 (the direction of arrow L). Therefore, the misalignment in the length direction between adjacent extractors 50 or between an extractor 50 and a connecting component 51 adjacent to each other may be suppressed.

In each extractor 50 and the connecting component 51, three connecting protrusions 57 and three connecting recesses 58 are formed. However, the numbers of the connecting protrusions 57 and the connecting recesses 58 may be set arbitrarily.

### Fourth Embodiment

Next, a fourth embodiment will be described.

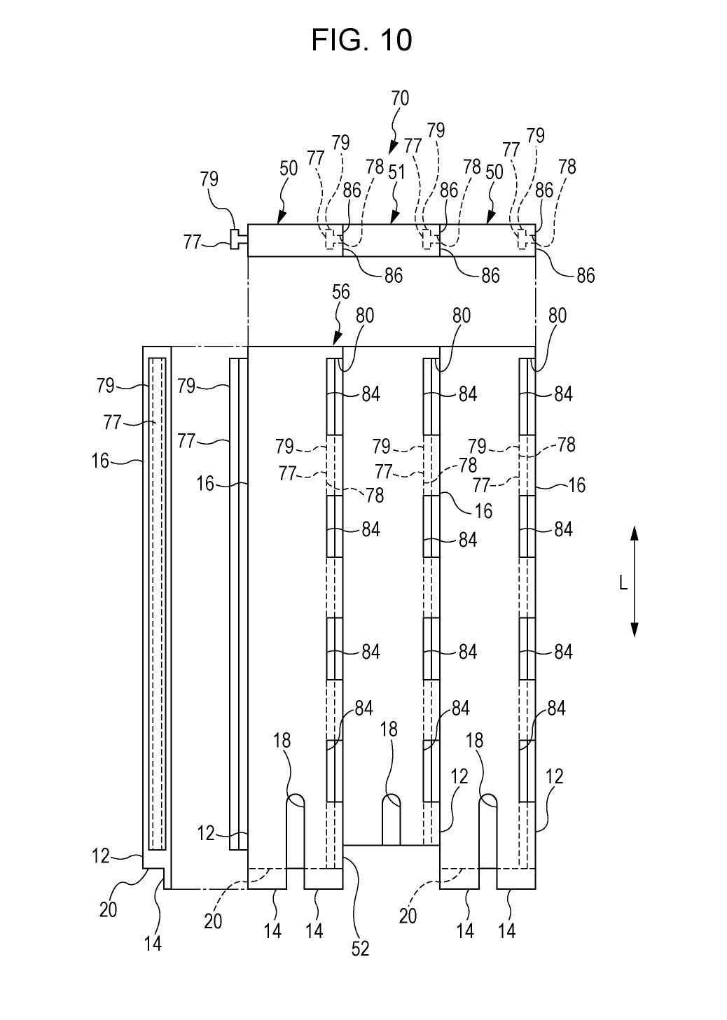

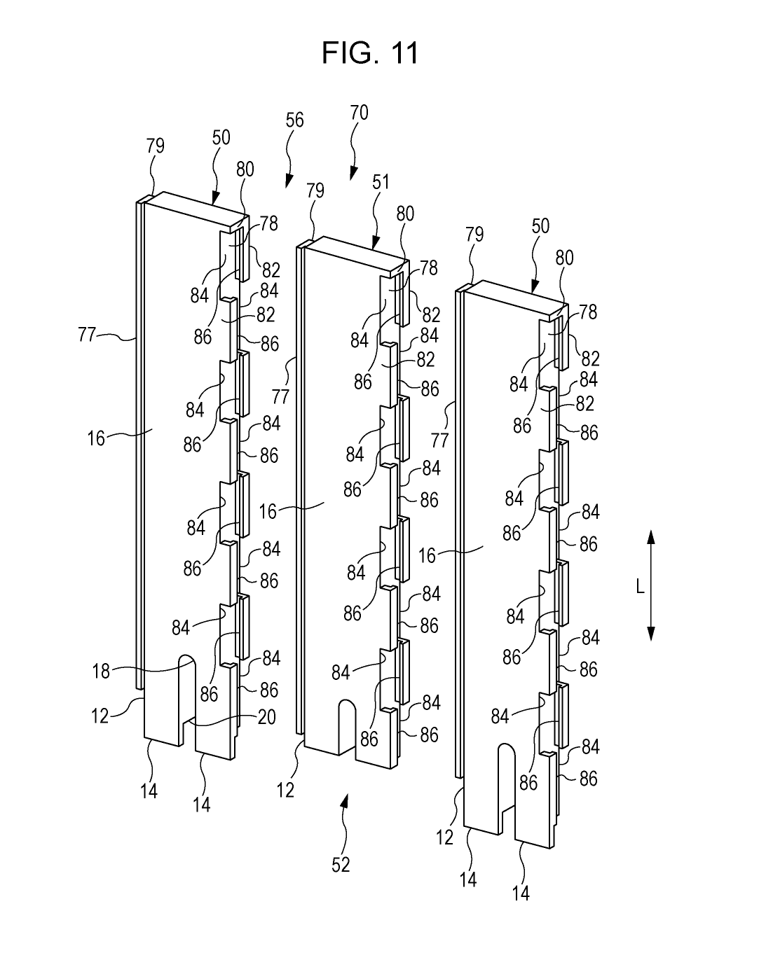

An extracting device 70 according to the fourth embodiment illustrated in FIG. 10 and FIG. 11 differs from the extracting device 40 according to the third embodiment in the configuration of the connecting portions 56.

That is, the connecting portions 56 each have a connecting protrusion 77 and a connecting recess 78. The connecting protrusion 77 is formed on one side of each of the extractors 50 and the connecting component 51, substantially throughout the length in the length direction thereof. The connecting protrusion 77 has a T-shaped cross-section, and an enlarged portion 79 is formed at the distal end thereof.

The connecting recess 78 is formed in the other side of each of the extractors 50 and the connecting component 51. The connecting recess 78 is formed like a groove extending substantially throughout the length in the length direction of the other side of each of the extractors 50 and the connecting component 51. In each extractor 50, the end of the connecting recess 78 closest to the distal end of the extractor 50 is open toward the distal end of the extractor 50, and the end of the connecting recess 78 closest to the rear end of the extractor 50 is terminated. Similarly, in the connecting component 51, the end of the connecting recess 78 closest to the distal end of the connecting component 51 is open toward the distal end of the connecting component 51, and the end of the connecting recess 78 closest to the rear end of the connecting component 51 is terminated.

As illustrated in FIG. 11, in each extractor 50, the end wall portion at the end of the connecting recess 78 closest to the rear end of the extractor 50 is formed as an engaging wall portion 80 that is engaged with the connecting protrusion 77. Similarly, in the connecting component 51, the end wall portion at the end of the connecting recess 78 closest to the rear end of the connecting component 51 is formed as an engaging wall portion 80 that is engaged with the connecting protrusion 77.

In a pair of first and second side wall portions 82 of the connecting recess 78 extending in the length direction of the extractors 50 and the connecting component 51, cutouts 84 are formed in a staggered manner. The first side wall portion 82 has, at positions corresponding to the cutouts 84 formed in the second side wall portion 82, engaging portions 86 protruding toward these cutouts 84. Similarly, the second side wall portion 82 has, at positions corresponding to the cutouts 84 formed in the first side wall portion 82, engaging portions 86 protruding toward these cutouts 84. The engaging portions 86 are formed at the end in the height direction of each side wall portion 82 (that is, at the end of each side wall portion 82 closest to the opening of the groove-like engaging recess 78).

The above-described connecting protrusion 77 is inserted into the connecting recess 78 through the opening at the distal end of the extractor 50 or the connecting component 51, and is slid in the connecting recess 78. When the end of the connecting protrusion 77 closest to the rear end of the extractor 50 or the connecting component 51 is engaged with the engaging wall portion 80, the connecting protrusion 77 is fitted in the connecting recess 78. When the connecting protrusion 77 is fitted in the connecting recess 78, the enlarged portion 79 is engaged with the engaging portions 86 in the direction in which the connecting protrusion 77 comes out from the connecting recess 78.

As in the extracting device 40 according to the third embodiment, in the extracting device 70 according to the fourth embodiment, a cutout 52 is formed between the tongue portions 14 of the adjacent extractors 50 by the connecting component 51. Therefore, the extracting device 70 may extract the memory cards that are desired to be extracted at once, while leaving the memory card that is not extracted.

Since the plurality of extractors 50 and the connecting component 51 may be rearranged, the memory card that is not extracted may be freely chosen by arbitrarily setting the position of the connecting component 51. Since the number of extractors 50 may also be freely chosen, the number of memory cards that are extracted at once may be adjusted.

When the connecting protrusion 77 is fitted in the connecting recess 78, the connecting protrusion 77 is engaged with the engaging wall portion 80 in the length direction of the extractors 50 and the connecting component 51 (the direction of arrow L). Therefore, the misalignment in the length direction between adjacent extractors 50 or between an extractor 50 and a connecting component 51 adjacent to each other may be suppressed.

When the connecting protrusion 77 is fitted in the connecting recess 78, the enlarged portion 79 is engaged with the engaging portions 86 in the direction in which the connecting protrusion 77 comes out from the connecting recess 78. Therefore, the coming out of the connecting protrusion 77 from the connecting recesses 78, that is, the separation of a plurality of extractors 50 or the separation of an extractor 50 and a connecting component 51 may be suppressed.

The side wall portions 82 of the connecting recess 78 have cutouts 84 at positions corresponding to the engaging portions 86. Therefore, when the extractors 50 and the connecting component 51 are formed of resin, the connecting recess 78 may be easily formed.

Although the connecting protrusion 77 and the connecting recess 78 are formed substantially throughout the length of each extractor 50 and the connecting component 51, the connecting protrusion 77 and the connecting recess 78 may be divided in the length direction of the extractors 50 and the connecting component 51.

Although embodiments of the present disclosure have been described above, the present disclosure is not limited to the above embodiments, and may be embodied in other specific forms without departing from the spirit of the present disclosure.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. An extractor comprising:
an attachment portion that has at least one groove receiving a side portion of a board connected to a connector and that is attached to the side portion of the board;
a tongue portion that extends from a side portion of the at least one groove in the attachment portion along the extension direction of the at least one groove and that is engaged with the inner surface of a latch, the board being pushed up by inclining toward the side of the board; and
an operating portion that extends from the attachment portion in the opposite direction from the tongue portion.

2. The extractor according to claim 1,
wherein a stepped surface that is in contact with an upper end surface of the latch is formed at the end of the attachment portion closest to the tongue portion.

3. The extractor according to claim 1,
wherein when the stepped surface is in contact with the upper end surface of the latch, a gap is formed between an end wall portion on the opposite side of the at least one groove from the tongue portion and the upper end surface of the board.

4. The extractor according to claim 3,
wherein when the board is pushed up and disconnected from the connector, the end wall portion is brought into contact with the upper end surface of the board.

5. The extractor according to claim 1,
wherein when the board is pushed up and disconnected from the connector, the tongue portion is disengaged from the inner surface of the latch.

6. The extractor according to claim 1,
wherein when the operating portion is rotated about a rotation fulcrum that is the contact point between the bottom of the at least one groove and the upper corner of the board, a second distance from the rotation fulcrum to the rear end of the operating portion is greater than a first distance from the rotation fulcrum to the distal end of the tongue portion.

7. The extractor according to claim 1,
wherein the extractor is used for the connector that corresponds to a dual inline memory module (DIMM) standard, and a memory card that is the board that of the DIMM.

8. The extractor according to claim 1,
wherein the attachment portion includes a plurality of grooves, and the tongue portion extends from the side portion of each of the plurality of grooves.

9. The extractor according to claim 1,
wherein the at least one groove comprises a plurality of grooves, the tongue portions extend from the side portions of each of one or some of the plurality of grooves, and the attachment portion has, at a position or positions corresponding to the other groove or grooves, a cutout or cutouts extending in the opposite direction from the direction in which the tongue portions extend.

10. An extracting device comprising:
a plurality of extractors each comprising
an attachment portion that has a groove receiving a side portion of a board connected to a connector and that is attached to the side portion of the board,
a tongue portion that extend from a side portion of the groove in the attachment portion along an extension direction of the groove and that is engaged with an inner surface of a latch to push up the board by inclining toward the side of the board, and
an operating portion that extends from the attachment portion in the opposite direction from the tongue portion; and
a connecting component that is placed between adjacent two of the plurality of extractors, that connects the adjacent extractors, and that forms a cutout extending in the opposite direction from the direction in which the tongue portions extend, between the tongue portions of the adjacent extractors.

11. The extracting device according to claim 10,
wherein the connecting component is the same as each extractor from which the tongue portions are omitted.

12. The extracting device according to claim 11, further comprising connecting portions that connect the plurality of the extractors and the connecting component such that the plurality of the extractors and the connecting component may be rearranged.

13. The extracting device according to claim 12,
wherein the connecting portions each have a connecting protrusion that is formed on one side of each of the extractors and the connecting component, and a connecting recess that is formed in the other side of each of the extractors and the connecting component, and in which the connecting protrusion is fitted.

14. The extracting device according to claim 13,
wherein the connecting recess has engaging wall portions that are engaged with the connecting protrusion in the length direction of the extractors and the connecting component.

15. The extracting device according to claim 13,
wherein an enlarged portion is formed at the distal end of the connecting protrusion, and engaging portions that are engaged with the enlarged portion in the direction in which the connecting protrusion comes out from the connecting recess are formed at the end of the connecting recess closest to the opening of the connecting recess.
